(19) United States
(12) Patent Application Publication
(10) Pub. No.: US 2022/0374189 A1
(43) Pub. Date: Nov. 24, 2022

(54) TILED DISPLAY DEVICE

(71) Applicant: InnoLux Corporation, Miao-Li County (TW)

(72) Inventors: Shu-Ming KUO, Miao-Li County (TW); Jian-Jung SHIH, Miao-Li County (TW); Tsau-Hua HSIEH, Miao-Li County (TW); Chih-Yung HSIEH, Miao-Li County (TW)

(21) Appl. No.: 17/817,720

(22) Filed: Aug. 5, 2022

Related U.S. Application Data
(62) Division of application No. 16/199,514, filed on Nov. 26, 2018.
(60) Provisional application No. 62/598,016, filed on Dec. 13, 2017.

(30) Foreign Application Priority Data
May 25, 2018 (CN) 201810516246.2

(51) Int. Cl. G06F 3/14; H01L 27/32; G09F 9/302; G02F 1/1333; G09G 3/32; G09G 3/20; G09G 3/3208

(52) U.S. Cl. CPC G06F 3/1446; H01L 27/3213; H01L 27/3293; G09F 9/3026; G02F 1/13336; G09G 3/32; G09G 3/2003; G09G 3/2074; G09G 3/3208; H01L 27/3237; G09G 2300/026; G09G 2300/0426; G09G 2300/023; G09G 2300/0408

(57) ABSTRACT

A tiled display device is provided. The tiled display device includes a first panel and a second panel adjacent to the first panel. The first panel includes a first pixel unit, a second pixel unit and a third pixel unit. The second panel includes a fourth pixel unit, a fifth pixel unit, a sixth pixel unit, a seventh pixel unit, an eighth pixel unit and a ninth pixel unit. The second pixel unit, the fifth pixel unit, and the eighth pixel unit are arranged in a column and have a first color. The first pixel unit, the sixth pixel unit, and the seventh pixel unit are arranged in a column and have a second color. The third pixel unit, the fourth pixel unit and the ninth pixel unit are arranged in a column and have a third color.

### CROSS REFERENCE TO RELATED APPLICATIONS

This application is a Divisional of U.S. patent application Ser. No. 16/199,514 filed on Nov. 26, 2018, which claims priority of China Patent Application No. 201810516246.2 filed on May 25, 2018, and also claims priority of a provisional application of U.S. Patent Application No. 62/598,016 filed on Dec. 13, 2017, the entirety of which is incorporated by reference herein.

### BACKGROUND OF THE INVENTION

### Field of the Invention

The embodiments of the disclosure relate to a tiled display device, and in particular to a tiled display device with a reduced gap or a tiled display of low color mismatching.

### Description of the Red Pixel Related Art

As digital technology develops, display devices are widely used. Today, mass production of large display device is trendy in the display industry, and any reduction of production cost or process steps may bring huge economic benefits. In addition, quick and efficient information delivery has been regarded as one of the competitive indicators. Since the Public Information Display (PID) can provide instant and diverse information, it has gradually replaced the traditional bulletin board. The trend of public information displays has moved toward large size and high resolution. Therefore, companies in display panel industry are devoted to develop large-size, high-resolution display devices, and the tiled display technology also becomes more and more important.

Therefore, the development of a tiled display device with high resolution and non-obvious seams has become valuable.

### BRIEF SUMMARY OF THE INVENTION

Some embodiments of the present disclosure provide a tiled display device. The tiled display device includes a first panel. The first panel includes a first pixel unit, a second pixel unit and a third pixel unit. The second pixel unit is between the first pixel unit and the third pixel unit. The tiled display device also includes a second panel adjacent to the first panel. The second panel includes a fourth pixel unit corresponding and adjacent to the first pixel unit, a fifth pixel unit corresponding and adjacent to the second pixel unit and a sixth pixel unit corresponding and adjacent to the third pixel unit. The fifth pixel unit is between the fourth pixel unit and the sixth pixel unit. The second panel also includes a seventh pixel unit adjacent to the fourth pixel unit. The fourth pixel unit is between the first pixel unit and the seventh pixel unit. The second panel further includes an eighth pixel unit adjacent to the fifth pixel unit. The fifth pixel unit is between the second pixel unit and the eighth pixel unit. In addition, the second panel includes and a ninth pixel unit adjacent to the sixth pixel unit. The sixth pixel unit is between the third pixel unit and the ninth pixel unit. The second pixel unit, the fifth pixel unit and the eighth pixel unit have a first color, the first pixel unit, the sixth pixel unit and the seventh pixel unit have a second color, the third pixel unit, the fourth pixel unit and the ninth pixel unit have a third color, and the first color, the second color and the third color are different colors.

Some embodiments of the present disclosure provide a tiled display device. The tiled display device includes a first panel having a first side, a second side opposite to the first side and a first top surface that is connected to the first side and the second side. The first panel comprises: a first pixel unit, a second pixel unit and a third pixel unit, wherein the second pixel unit is between the first pixel unit and the third pixel unit. The first panel also includes a first circuit portion disposed on the first top surface and adjacent to at least one of the first side and the second side. The tiled display device also includes a second panel adjacent to the first panel, wherein the second panel has a third side that is corresponding and adjacent to the second side, and a fourth side opposite to the third side. The second panel includes a fourth pixel unit corresponding and adjacent to the first pixel unit, a fifth pixel unit corresponding and adjacent to the second pixel unit and a sixth pixel unit corresponding and adjacent to the third pixel unit, wherein the fifth pixel unit is between the fourth pixel unit and the sixth pixel unit. The second panel also includes a second circuit portion disposed on a second top surface that is connected to the third side and the fourth side, wherein the second circuit portion is disposed adjacent to at least one of the third side and the fourth side. The second pixel unit and the fifth pixel unit have a first color, the first pixel unit and the fourth pixel unit have a second color, the third pixel unit and the sixth pixel unit have a third color, and the first color, the second color and the third color are different colors.

Some embodiments of the present disclosure provide a tiled display device. The tiled display device includes a first panel which including a first pixel unit, a second pixel unit, and a third pixel unit. The tiled display device also includes a second panel adjacent to the first panel. The second panel includes a fourth pixel unit corresponding to the first pixel. The tiled display device further includes a first circuit board disposed on a first top surface of the first panel. The first circuit board has a first portion disposed on the first top surface and a connected portion that is connected to the first portion. The connected portion is located between the first panel and the second panel. The sum of the width of the first portion and a thickness of the connected portion is less than a first distance between the first pixel unit and the fourth pixel unit.

### BRIEF DESCRIPTION OF THE DRAWINGS

The disclosure may be more fully understood by reading the subsequent detailed description and examples with references made to the accompanying drawings, wherein:

FIG. 1A is a top view of a first panel of a tiled display device in accordance with some embodiments of the present disclosure;

FIG. 1B is a top view of a second panel of a tiled display device in accordance with some embodiments of the present disclosure;

FIG. 2 is a cross-sectional view of a light-emitting unit in accordance with some embodiments of the present disclosure;

FIG. 3 is a top view of a tiled display device in accordance with some embodiments of the present disclosure;

FIGS. 4-6 are top views of a tiled display device in accordance with some embodiments of the present disclosure;

FIGS. 7-11 are top views of a panel of a tiled display device in accordance with some embodiments of the present disclosure;

FIG. 12 is an enlarged view of a tiled display device shown in FIG. 14 in accordance with some embodiments of the present disclosure;

FIG. 13 is an enlarged view of a tiled display device shown in FIG. 14 in accordance with some embodiments of the present disclosure;

FIG. 14 is a cross-sectional view of a tiled display device in accordance with some embodiments of the present disclosure.

### DETAILED DESCRIPTION OF THE INVENTION

The display device of the present disclosure is described in detail in the following description. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. In addition, the drawings of different embodiments may use like and/or corresponding numerals to denote like and/or corresponding elements in order to clearly describe the present disclosure. However, the use of like and/or corresponding numerals in the drawings of different embodiments does not suggest any correlation between different embodiments. In addition, in this specification, expressions such as “first material layer disposed on/over a second material layer”, may indicate the direct contact of the first material layer and the second material layer, or it may indicate a non-contact state with one or more intermediate layers between the first material layer and the second material layer. In the above situation, the first material layer may not be in direct contact with the second material layer.

It should be noted that the elements or devices in the drawings of the present disclosure may be present in any form or configuration known to those skilled in the art. In addition, the expression “a layer overlying another layer”, “a layer is disposed above another layer”, “a layer is disposed on another layer” and “a layer is disposed over another layer” may indicate that the layer is in direct contact with the other layer, or that the layer is not in direct contact with the other layer, there being one or more intermediate layers disposed between the layer and the other layer.

The terms “about” and “substantially” typically mean+/−20% of the stated value, more typically +/−10% of the stated value, more typically +/−5% of the stated value, more typically +/−3% of the stated value, more typically +/−2% of the stated value, more typically +/−1% of the stated value and even more typically +/−0.5% of the stated value. The stated value of the present disclosure is an approximate value. When there is no specific description, the stated value includes the meaning of “about” or “substantially”.

It should be understood that, although the terms first, second, third etc. may be used herein to describe various elements, components, regions, layers, portions and/or sections, these elements, components, regions, layers, portions and/or sections should not be limited by these terms. These terms are only used to distinguish one element, component, region, layer, portion or section from another region, layer or section. Thus, a first element, component, region, layer, portion or section discussed below could be termed a second element, component, region, layer, portion or section without departing from the teachings of the present disclosure.

Unless defined otherwise, all technical and scientific terms used herein have the same meaning as commonly understood by one of ordinary skill in the art to which this disclosure belongs. It should be appreciated that, in each case, the term, which is defined in a commonly used dictionary, should be interpreted as having a meaning that conforms to the relative skills of the present disclosure and the background or the context of the present disclosure, and should not be interpreted in an idealized or overly formal manner unless so defined.

This description of the exemplary embodiments is intended to be read in connection with the accompanying drawings, which are to be considered part of the entire written description. The drawings are not drawn to scale. In addition, structures and devices are shown schematically in order to simplify the drawing.

The term “substrate” is meant to include devices formed within a substrate or the layers overlying the substrate. All transistor elements needed may be already formed over the substrate. However, the substrate is represented with a flat surface in order to simplify the drawing. The term “substrate surface” is meant to include the uppermost exposed layers on a substrate, such as an insulating layer and/or conductive wires.

The thickness of a structure described in the embodiments of the disclosure indicates a value for the average thickness of the structure after deleting outliers. The outliers can be the thickness of an edge, an obvious micro-trench, or an obvious micro-raised area. After deleting the outliers, most values of the thickness are within a range of plus or minus three standard deviations.

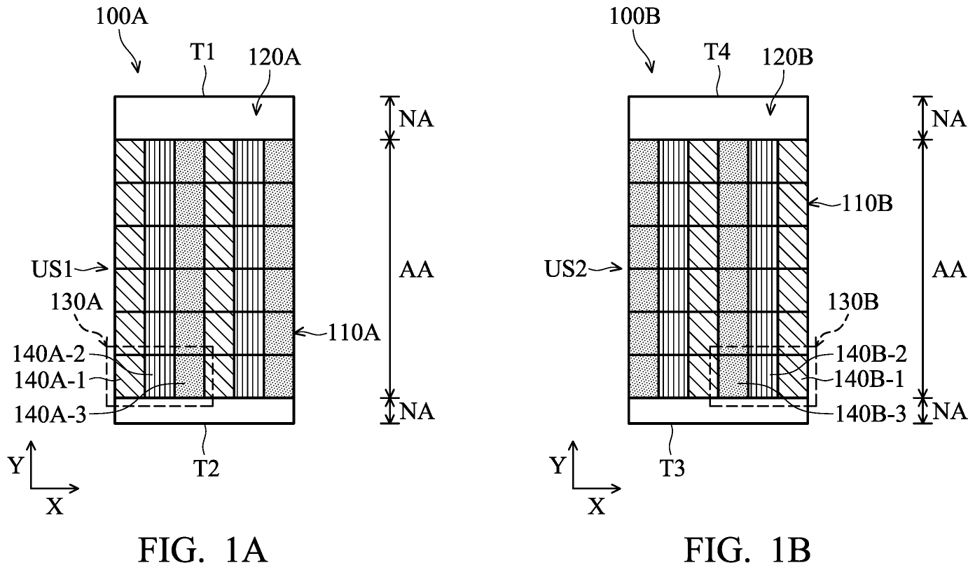

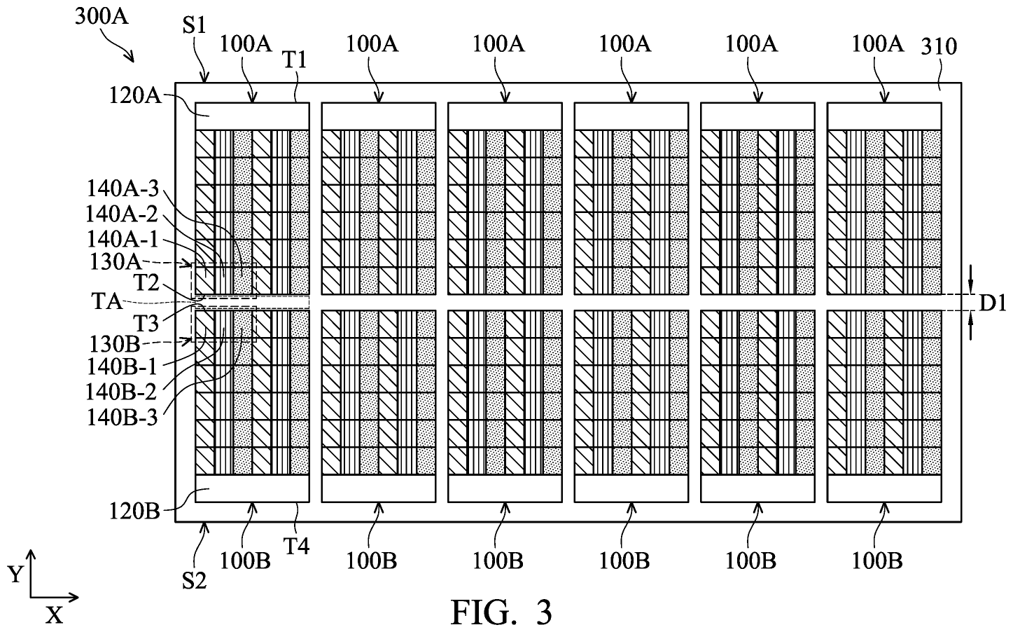

Referring to FIGS. 1A, 1B and 3, a tiled display device 300A is provided. The tiled display device 300A includes a first panel 100A (FIGS. 1A and 3) and a second panel 100B (FIGS. 1B and 3) adjacent to the first panel 100A. As shown in FIG. 1A, the first panel 100A has a first side T1, a second side T2 opposite to the first side T1, and a first top surface US1 that is connected to the first side T1 and the second side 12. The first panel 100A includes a first pixel unit 140A-1, a second pixel unit 140A-2 and a third pixel unit 140A-3. The second pixel unit 140A-2 is located between the first pixel unit 140A-1 and the third pixel unit 140A-3. As shown in FIG. 1B, the second panel 100B has a third side T3, a fourth side T4 opposite to the third side T3, and a second top surface US2 that is connected to the third side T3 and the fourth side T4. The second panel 100B includes a fourth pixel unit 140B-1, a fifth pixel unit 140B-2 and a sixth pixel unit 140B-3. The fifth pixel unit 140B-2 is located between the fourth pixel unit 140B-1 and the sixth pixel unit 140B-3. As shown in FIG. 3, the fourth pixel unit 140B-1 is corresponding and adjacent to the first pixel unit 140A-1, the fifth pixel unit 140B-2 is corresponding and adjacent to the second pixel unit 140A-2, and the sixth pixel unit 140B-3 is corresponding and adjacent to the third pixel unit 140A-3. The first panel 100A may include a first circuit portion 120A, and the second panel 100B may include a second circuit portion 120B. The first circuit portion 120A is disposed on the first top surface US1 and adjacent to at least one of the first side T1 and the second side T2. The second circuit portion 120B is disposed on the second top surface US2 and adjacent to at least one of the third side T3 and the fourth side T4. In addition, the second pixel unit 140A-2 and the fifth pixel unit 140B-2 have a first color, the first pixel unit 140A-1 and the fourth pixel unit 140B-1 have a second color, and the third pixel unit 140A-3 and the sixth pixel unit 140B-3 have a third color. The first color, the second color and the third color are different colors, and the scope of the disclosure is not intended to be limiting.

The embodiment shown in FIGS. 1A, 1B and 3 shows that the first circuit portion 120A is adjacent to the first side T1, and the second circuit portion 120B is adjacent to the fourth side T4. However, the scope of the disclosure is not intended to be limiting. In other embodiments, the first circuit portion 120A may be adjacent to the second side T2. In other embodiments, the second circuit portion 120B may be adjacent to the third side T3.

More specifically, FIG. 1A is a top view of a first panel 100A in accordance with some embodiments of the present disclosure. The first panel 100A may include a first substrate 110A. The first substrate 110A may include, but is not limited to, various elements and layers such as circuits, transistors, conductive pads or dielectric layers. The first substrate 110A may include, but is not limited to, glass substrate, plastic substrate, flexible substrate, flexible printed circuit board (FPCB) or hard printed circuit board. The material of the first substrate 110A may include, but is not limited to, glass, quartz, sapphire, organic polymer or metal. When the first substrate 110A is a flexible substrate, the material may be, but is not limited to, polycarbonate (PC), polyimide (PI), polypropylene (PP), polyethylene terephthalate (PET), another suitable material, or a combination thereof.

In some embodiments, the first panel 100A includes a display region AA and a non-display region NA. The non-display region NA may be adjacent to one or two sides of the display region AA, or it may surround the display region AA, and the scope of the disclosure is not intended to be limiting. As shown in FIG. 1A, the first circuit portion 120A may be disposed on the first top surface US1 of the first substrate 110A and correspond to the non-display region NA. The first circuit portion 120A may be adjacent to the first side T1, but the scope of the disclosure is not intended to be limiting. In some embodiments, the first circuit portion 120A may not be disposed adjacent to the second side T2. In some embodiments, the first circuit portion 120A may be disposed on the first top surface US1 and adjacent to the non-display region NA of the first side T1 and the second side T2. In some embodiments, the first circuit portion 120A may be disposed on the first top surface US1 and adjacent to other non-display regions NA of the first panel 100A. FIG. 1A illustrates that the first panel 100A has the first circuit portion 120A at the first side T1 and an additional circuit portion at the second side T2, and the scope of the disclosure is not intended to be limiting. In some embodiments, there is no additional circuit portion at the second side T2. In some other embodiments, the additional circuit portion may be bent so that the additional circuit portion can be moved to the backside (not shown) of the first substrate.

More specifically, FIG. 1B is a top view of a second panel 100B in accordance with some embodiments of the present disclosure. As shown in FIG. 1B, the second circuit portion 120B may be disposed on the second top surface US2 of the second substrate 110B and correspond to the non-display region NA. The second circuit portion 120B may be adjacent to the fourth side T4, and the scope of the disclosure is not intended to be limiting. In some embodiments, the second circuit portion 120B may not be disposed adjacent to the third side T3. However, the scope of the disclosure is not intended to be limiting. In some embodiments, the second circuit portion 120B may be disposed on the second top surface US2 and adjacent to the non-display region NA of the third side T3 and the fourth side T4. In some embodiments, the second circuit portion 120B may be disposed on the second top surface US2 and adjacent to other non-display regions NA of the second panel 100B. FIG. 1B illustrates that the second panel 100B has the second circuit portion 120B at the fourth side T4 and an additional circuit portion at the third side T3, and the scope of the disclosure is not intended to be limiting. In some embodiments, there is no additional circuit portion at the fourth side T4. In some embodiments, the additional circuit portion may be bent so that the additional circuit portion can be moved to the backside (not shown) of the second substrate 110B.

The first circuit portion 120A and the second circuit portion 120B may include a plurality of conductive wires (not shown) or a plurality of conductive pads (not shown), but the scope of the disclosure is not intended to be limiting.

As shown in FIG. 1A, the first panel 100A may further include a plurality of display portions 130A. The display portion 130A may be disposed on the first top surface US1 of the first substrate 110A and correspond to the display region AA. A display portion 130A may include, but is not limited to, a blue pixel unit (oblique screentone), a green pixel unit (vertical screentone) and a red pixel unit (dot screentone). As shown in FIGS. 1A and 3, the first pixel unit 140A-1 may be the blue pixel unit, the second pixel unit 140A-2 may be the green pixel unit, the third pixel unit 140A-3 may be the red pixel unit, but the scope of the disclosure is not intended to be limiting.

As shown in FIG. 1B, the second panel 100B may further include a plurality of display portions 130B. The display portion 130B may be disposed on the second top surface US2 of the second substrate 110B and correspond to the display region AA. Every display portion 130B may include, but is not limited to, a blue pixel unit (oblique screentone), a green pixel unit (vertical screentone) and a red pixel unit (dot screentone). As shown in FIGS. 1B and 3, the fourth pixel unit 140B-1 may be the blue pixel unit, the fifth pixel unit 140B-2 may be the green pixel unit, the sixth pixel unit 140B-3 may be the red pixel unit, but the scope of the disclosure is not intended to be limiting.

In some embodiments, the blue pixel unit, the green pixel unit and the red pixel unit mentioned above may be exchanged with each other, but the color in the second pixel unit 140A-2 and the fifth pixel unit 140B-2 is still the same color, the color in the first pixel unit 140A-1 and the fourth pixel unit 140B-1 is still the same color, and the color in the third pixel unit 140A-3 and the sixth pixel unit 140B-3 is still the same color, meanwhile the colors in the first pixel unit 140A-1, the second pixel unit 140A-2, the third pixel unit 140A-3 are different colors. It should be noted that the pixel units shown in figures have different screentones, and the pixel units with the same screentone have the same color. As shown in FIGS. 1A and 1B, in the first panel 100A or the second panel 100B, the pixel units in the same column have the same color. The aforementioned pixel units in the same column may be arranged along the Y-direction.

In some embodiments, as shown in FIGS. 1A and 1B, the arrangements of the pixel units of the first panel 100A and the second panel 100B are different. If the seam between the first panel 100A and the second panel 100B extending along the Y-direction is regarded as the axis of symmetry, the arrangement of the pixel units of the first panel 100A and that of the second panel 100B are mirror images of one another. The Y-direction may have different definitions according to different embodiments of the present disclosure. For example, as shown in FIG. 3, the seam TA between the first panel 100A and the second panel 100B has an extending direction, and the extending direction of the seam TA may be defined as the X-direction. The Y-direction may be perpendicular to the X-direction and extends along the first top surface US1 of the first panel 100A. The definition of the Y-direction in different embodiments will be described in more detail in the following paragraph.

As shown in FIGS. 1A and 1B, the arrangement of the pixel units of the first panel 100A and the arrangement of the pixel units of the second panel 100B are mirror images of one another when the seam between the first panel 100A and the second panel 100B is regarded as the axis of symmetry. For example, to fix the fourth side T4 of the second panel 100B and the first side T1 of the first panel 100A at the left side, the second circuit portion 120B and the first circuit portion 120A are adjacent to the fourth side T4 and the first side T1, respectively. At this time, the pixel units of the first panel 100A may sequentially be the red pixel unit, the green pixel unit and the blue pixel unit which are arranged repeatedly along the X-direction. Meanwhile, the pixel units of the first panel 100A may sequentially be the blue pixel unit, the green pixel unit and the red pixel unit which are arranged repeatedly along the X-direction. However, the scope of the disclosure is not intended to be limiting.

In addition, in some embodiments, the plurality conductive wires (not shown) in the first circuit portion 120A or the second circuit portion 120B may be coupled to light-emitting units (not shown) such as red pixel units, green pixel units and the blue pixels, respectively. Moreover, the plurality conductive wires in the first circuit portion 120A or the second circuit portion 120B may be coupled to an outer circuit board (not shown) through the plurality of conductive pads (not shown) in the first circuit portion 120A or the second circuit portion 120B respectively. However, the scope of the disclosure is not intended to be limiting.

Materials in the pixel units may include, but is not limited to, liquid crystal (LC), organic light-emitting diode (OLED), quantum dot (QD), fluorescence material, phosphor material, light-emitting diode (LED), micro light-emitting diode (μLED), mini light-emitting diode, other suitable display mediums, or the combination thereof. However, the scope of the disclosure is not intended to be limiting.

In some embodiments, the pixel light-emitting unit is the micro light-emitting diode, and one pixel unit may include at least one light-emitting unit 200. In some embodiments, the pixel unit may include two or more light-emitting units 200. More specifically, at least one of the two or more light-emitting units 200 may emit light within a range of wavelength. However, the scope of the disclosure is not intended to be limiting.

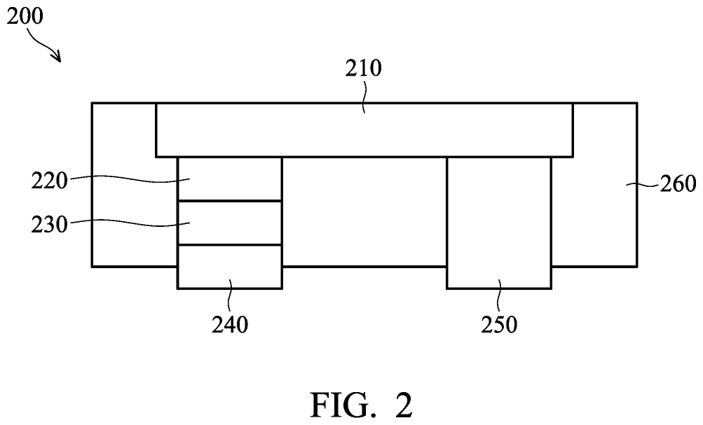

FIG. 2 is a cross-sectional view of a light-emitting unit 200 in accordance with some embodiments of the present disclosure. As shown in FIG. 2, when the light-emitting unit 200 is the mini light-emitting diode or the micro light-emitting diode, the light-emitting unit 200 includes a semiconductor layer 210, a light-emitting layer 220, and a semiconductor layer 230. The semiconductor layer 210 and the semiconductor layer 230 may electrically connect to a conductive pad 240 or a conductive pad 250 respectively. The semiconductor layer 210 and the semiconductor layer 230 may include, but are not limited to, amorphous-Si, poly-Si, germanium, gallium nitride (GaN), silicon carbide, gallium arsenide, gallium phosphide, indium phosphide, indium arsenide and/or indium antimonide, SiGe alloy, GaAsP alloy, AlInAs alloy, AlGaAs alloy, GaInAs alloy, GaInP alloy, GaInAsP alloy, or a combination thereof. The semiconductor layer 210 and the semiconductor layer 230 may also include, but are not limited to, metal oxide such as indium gallium zinc oxide (IGZO), indium zinc oxide (IZO), indium gallium zinc oxide (IGZTO), polycyclic aromatic compound, or a combination thereof.

As shown in FIG. 2, the light-emitting layer 220 is disposed between the semiconductor layer 210 and the semiconductor layer 230. The light-emitting layer 220 may include, but is not limited to, homojunction, heterojunction, single-quantum well (SQW), multiple-quantum well (MQW) or any other applicable structure. In some embodiments, the light-emitting layer 220 includes un-doped n type InₓGa₍₁₋ₓ₎N. In other embodiments, the light-emitting layer 220 includes materials such as AlₓIn_{y}Ga_{(1-x-y)}N or other materials.

Moreover, the light-emitting layer 220 may include a multiple-quantum well structure with alternately arranged multiple-quantum layers (such as InGaN) and barrier layers (such as GaN).

As shown in FIG. 2, a protective layer 260 is disposed on sidewalls of the semiconductor layer 210, the light-emitting layer 220, the semiconductor layer 230, at least one conductive pad 240, or at least one other conductive pad 250. In some embodiments, the protective layer 260 is, but is not limited to, a reflective material or light absorptive material. When the protective layer 260 is the reflective material, the protective layer 260 may be a single reflective layer, or a multi-layer reflective structure including, but is not limited to, a distributed Bragg reflector (DBR), a combination of dielectric layer/metal layer/dielectric layer, or an Omni-Directional reflector (ODR). When the protective layer 260 is the light absorptive material, the protective layer 260 may include photoresist materials (such as a white photoresist or a black photoresist). It should be noted that at least one insulating layer is in the protective layer 260 to reduce the short between the protective layer 260 and other metal layers. For example, the surface of the protective layer 260 contacting the conductive pad 240 and the conductive pad 250 is electrically insulative. In some embodiments, the outside of the protective layer 260 is electrically insulative.

As shown in FIG. 2, the conductive pad 240 is deposed adjacent to the semiconductor layer 230, the conductive pad 250 is deposed adjacent to the semiconductor layer 210. The material of the conductive pad 240 or the conductive pad 250 may include, but is not limited to, copper (Cu), aluminum (Al), molybdenum (Mo), tungsten (W), gold (Au), chromium (Cr), nickel (Ni), platinum (Pt), titanium (Ti), iridium (Ir), Rhodium (Rh), any other applicable material, an alloy thereof, or the combination thereof.

The light-emitting unit 200 may be, but is not limited to, a lateral or a vertical structure. When the light-emitting unit 200 is a lateral structure, two electrodes are disposed on the same side of the light-emitting unit 200. When the light-emitting unit 200 is a vertical structure, two electrodes are disposed on different sides of the light-emitting unit 200.

FIG. 3 is a top view of a tiled display device 300A in accordance with some embodiments of the present disclosure. In some embodiments, the tiled display device 300A includes a substrate board 310, at least one first panel 100A and at least one second panel 100B. It should be noted that the second panel 100B shown in FIG. 3 is rotated 180° from the structure shown in FIG. 1B, and disposed corresponding and adjacent to the first panel 100A. The substrate board 310 is configured to support the first panel 100A and the second panel 100B, however the scope of the disclosure is not intended to be limiting. In some embodiments, wires (not shown) may be formed in the substrate board 310. The substrate board 310 is electrically connected to the first circuit portion 120A of the first panel 100A and the second circuit portion 120B of the second panel 100B through the wires. As a result, the outer circuit (not shown) can provide signals to control the display portion 130A and the display portion 130B, but the scope of the disclosure is not intended to be limiting. The detail will be described in detail in the following paragraph. FIG. 3 illustrates that the tiled display device 300A includes six first panels 100A and six second panels 100B. The number of the first panel 100A and the second panel 100B is merely an example, but the scope of the disclosure is not intended to be limiting. In other embodiments, the tiled display device 300A has more or less first panels 100A and second panels 100B.

In some embodiments, the first side T1 (the side adjacent to the first circuit portion 120A) of the first panel 100A is far from the fourth side T4 (the side adjacent to the second circuit portion 120B) of the second panel 100B. The plurality of first panels 100A may be arranged along the X-direction, and the plurality of second panels 100B may be arranged along the X-direction. The second side T2 of a first panel 100A, which is opposite to the first side T1, is adjacent to the third side T3 of a second panel 100B which is opposite to the fourth side T4. In some embodiments, there may be circuit boards (e.g. flexible printed circuit board, not shown), protective elements (not shown), adhesive elements (not shown), or other conductive elements between the second side T2 and the third side T3. In some embodiments, there is air between the second side T2 and the third side T3. In this embodiment, the additional circuit portions shown in FIGS. 1A and 1B are bent to the backsides of the first substrate 110A and the second substrate 110B respectively. Therefore, the additional circuit portions are not shown in the top view of FIG. 3.

In some embodiments, there is a first distance D1 between a unit pixel (e.g. the first pixel unit 140A-1) on the first panel 100A and the nearest unit pixel on the second panel 100B (e.g. the fourth pixel unit 140B-1) in the Y-direction. The first distance D1 may be defined as the minimum length along the Y-direction between the first pixel unit 140A-1 and the fourth pixel unit 140B-1. The first distance D1 will be described in detail in the following paragraph.

In some embodiments, as shown in FIG. 3, the second pixel unit 140A-2 and the fifth pixel unit 140B-2 may be the green pixel unit (vertical screentone), the first pixel unit 140A-1 and the fourth pixel unit 140B-1 may be the blue pixel unit (oblique screentone), and the third pixel unit 140A-3 and the sixth pixel unit 140B-3 may be the red pixel unit (dot screentone). However, the scope of the disclosure is not intended to be limiting. In addition, the second pixel unit 140A-2 is adjacent and corresponding to the fifth pixel unit 140B-2 along the Y-direction, the first pixel unit 140A-1 is adjacent and corresponding to the fourth pixel unit 140B-1 along the Y-direction, and the third pixel unit 140A-3 is adjacent and corresponding to the sixth pixel unit 140B-3 along the Y-direction. The aforementioned colors are merely an example, but the scope of the disclosure is not intended to be limiting. In other embodiments, the color of the pixels may be exchanged.

It should be noted that if a tiled display is manufactured by putting the panels with same pixel arrangement together and making these panels face each other, the color mismatch will occur. For example, when two first panels 100A are disposed facing each other and the first side T1 of one first panel 100A is far from the first side T1 of the other first panel 100A, then the blue pixel unit (oblique screentone) of the first panel 100A near the first side Si of the substrate board 310A, is adjacent and corresponding to the red pixel unit (dot screentone) of the first panel 100A near a second side S2 of the substrate board 310A. Therefore, a color mismatch will occur due to a difference in the color distribution between different panels when the viewer sees the tiled display device. In the embodiments of the present disclosure shown in FIG. 3, the configuration of two facing panels which are mirror images of one another (e.g. the first panel 100A and the second panel 100B) may decrease the problem of color mismatching.

It should be noted that although the first pixel unit 140A-1, the second pixel unit 140A-2 and the third pixel unit 140A-3 are illustrated in FIGS. 1A and 3 as being disposed close to each other, but in practice, there may be a pitch between any two of the first pixel unit 140A-1, the second pixel unit 140A-2 and the third pixel unit 140A-3 along the X-direction or the Y-direction. It will be described in detail in the following paragraph.

In some embodiments, the first circuit portion 120A and the second circuit portion 120B may be disposed adjacent to two opposite sides of the substrate board 310 respectively. For example, the first circuit portion 120A is disposed adjacent to the first side S1, and the second circuit portion 120B is disposed adjacent to the second side S2. In addition, there is no first circuit portion 120A, second circuit portion 120B or other circuit portions at the seam TA between the second side T2 and the third side T3. As a result, the first distance D1 can be decreased due to the omission of the area for disposing the first circuit portion 120A or the second circuit portion 120B or other circuit portions. Therefore, the quality of the tiled display device 300A is improved.

Many variations and/or modifications can be made to the embodiments of the disclosure. In some embodiments, the tiled display device is composed of a plurality of same panels which have the same arrangement of pixel units.

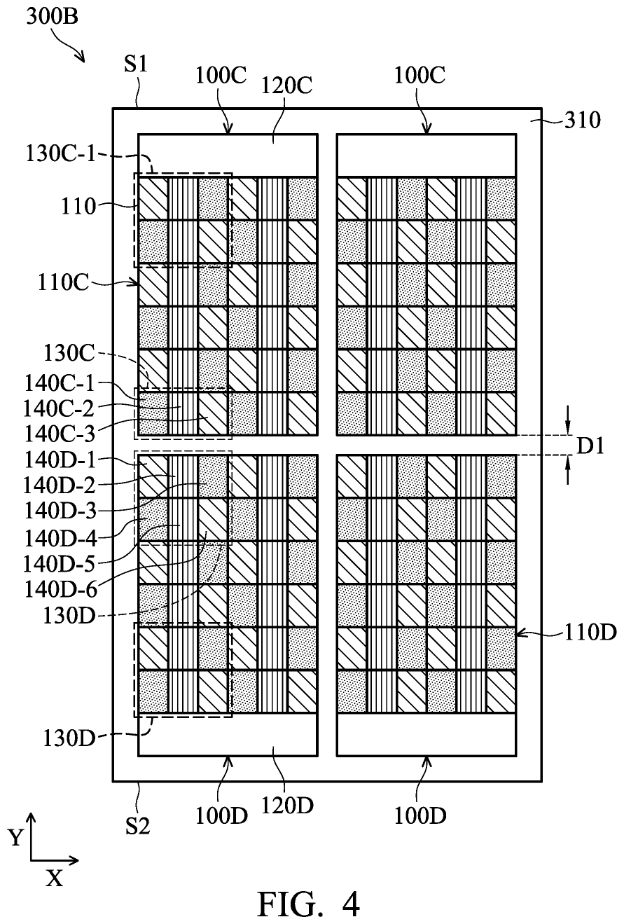

FIG. 4 is a top view of a tiled display device 300B in accordance with some embodiments of the present disclosure. The tiled display device 300B includes first panels 100C and second panels 100D that are adjacent to the first panel 100C. A display portion 130C of the first panel 100C may include a first pixel unit 140C-1, a second pixel unit 140C-2 and a third pixel unit 140C-3. The second pixel unit 140C-2 is disposed between the first pixel unit 140C-1 and the third pixel unit 140C-3. A display portion 130D of the second panel 100D may include a fourth pixel unit 140D-1, a fifth pixel unit 140D-2, a sixth pixel unit 140D-3, a seventh pixel unit 140D-4, an eighth pixel unit 140D-5 and a ninth pixel unit 140D-6. The fifth pixel unit 140D-2 is disposed between the fourth pixel unit 140D-1 and the sixth pixel unit 140D-3, and the eighth pixel unit 140D-5 is disposed between the seventh pixel unit 140D-4 and the ninth pixel unit 140D-6. In addition, the first pixel unit 140C-1 is adjacent and corresponding to fourth pixel unit 140D-1, the second pixel unit 140C-2 is adjacent and corresponding to fifth pixel unit 140D-2, and the third pixel unit 140C-3 is adjacent and corresponding to sixth pixel unit 140D-3. Moreover, the seventh pixel unit 140D-4 is adjacent to the fourth pixel unit 140D-1, the eighth pixel unit 140D-5 is adjacent to the fifth pixel unit 140D-2 and the ninth pixel unit 140D-6 is adjacent to the sixth pixel unit 140D-3. Furthermore, the fourth pixel unit 140D-1 is located between the first pixel unit 140C-1 and the seventh pixel unit 140D-4, the fifth pixel unit 140D-2 is located between the second pixel unit 140C-2 and the eighth pixel unit 140D-5, and the sixth pixel unit 140D-3 is located between the third pixel unit 140C-3 and the ninth pixel unit 140D-6. As shown in FIG. 4, the second pixel unit 140C-2, the fifth pixel unit 140D-2 and the eighth pixel unit 140D-5 have a first color. The first pixel unit 140C-1, the sixth pixel unit 140D-3 and the seventh pixel unit 140D-4 have a second color. The third pixel unit 140C-3, the fourth pixel unit 140D-1 and the ninth pixel unit 140D-6 have a third color. The first, second and third colors are different colors.

More specially, the tiled display device 300B includes two first panels 100C and two second panels 100D. However, the number of the first panel 100C and the second panel 100D is merely an example, but the scope of the disclosure is not intended to be limiting. The display portion 130C-1 of the first panel 100C may have six pixel units which are arranged in two rows and three columns. The pixel units in the same row may be defined as the pixel units arranged along the X-direction. In some embodiments, the arrangement of the pixel units of the display portion 130C-1 may be configured to that the middle pixels of the first and the second rows have the same color. The left and the right pixels of the first row may be configured to have other two colors that are different from the color of the middle pixel. In some embodiments, the left pixel of the second row and the right pixel of the first row have the same color such as blue, the right pixel of the second row and the left pixel of the first row have the same color such as red, and the middle pixels of the first and second rows have the same color such as green. In this configuration, the middle pixels of the first and the second rows are used as an axis. The left pixel and the right pixel of the first row, and the left pixel and the right pixel of the second row are configured to have an arrangement with a rotational symmetry. As shown in FIG. 4, the blue pixel unit (oblique screentone) of the first row is adjacent to the red pixel unit (dot screentone) of the second row, the green pixel unit (vertical screentone) of the first row is adjacent to the green pixel unit (vertical screentone) of the second row, and the red pixel unit (dot screentone) of the first row is adjacent to the blue pixel unit (oblique screentone) of the second row. The aforementioned colors may be exchanged if the arrangement is in accordance with the rotational symmetry.

In some embodiments, as shown in FIG. 4, the tiled display device 300B includes the second panel 100D. The display portion 130D of the second panel 100D has six pixel units arranged in two rows, but the scope of the disclosure is not intended to be limiting. The arrangement of the display portion 130D is the same as that of the display portion 130C-1, and not repeatedly described herein.

In some embodiments, the first panels 100C may be arranged along the X-direction, and the second panels 100D may be arranged along the X-direction. Moreover, the second panels 100D may be arranged to be corresponding and adjacent to the first panel 100C. Accordingly, a first panel 100C and a second panel 100D are disposed along the Y-direction. In this embodiment, the first circuit portion 120C of the first panel 100C and the second circuit portion 120D of the second panel 100D are disposed adjacent to two opposite sides (e.g. the first side S1 and the second side S2) of the substrate board 310, respectively. However, the scope of the disclosure is not intended to be limiting. In other embodiments, the first circuit portion 120C of the first panel 100C or the second circuit portion 120D of the second panel 100D can be disposed far from the first side S1 and the second side S2.

As shown in FIG. 4, the tiled display device 300B has a number of pixel units arranged in columns. The pixel units in the same column are arranged along the Y-direction, and the pixel units in the same row are arranged along the Y-direction. For example, the first column (the leftmost column) may be an arrangement of the blue pixel unit (oblique screentone) and the red pixel unit (dot screentone) disposed alternatively from top to bottom. The second column may be an arrangement of only the green pixel units (vertical screentone). The third column may be an arrangement of the red pixel unit (dot screentone) and the blue pixel unit (oblique screentone) disposed alternatively from top to bottom. The pixel units of the first column and the third column in the same row have different colors. The aforementioned colors are merely exemplary, and the scope of the disclosure is not intended to be limiting.

The first panel 100C and the second panel 100D can have the same arrangement of the pixel units through the configuration of the rotational symmetry shown in FIG. 4. In this embodiment, the first substrate 110C of the first panel 100C and the second substrate 110D of the second panel 100D are two substrates produced in the same processes. As a result, the cost is decreased due to the same reticle used during the formation of the first substrate 110C and the second substrate 110D, the decreased usage of mother boards, or lowering the complexity in some manufacturing processes. For example, because the first substrate 110C and the second substrate 110D are obtained from the same mother board, and circuits and transistors of the first substrate 110C and the second substrate 110D are formed by the same lithography and etching process, the process is simplified. Furthermore, the mismatch of the pixel units is decreased by the configuration of the rotational symmetry shown in FIG. 4.

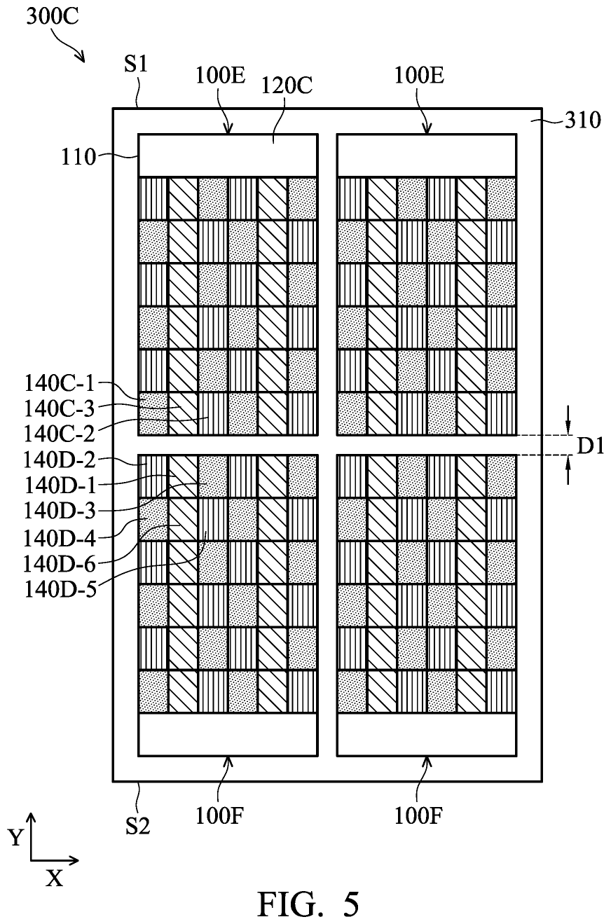

FIG. 5 is a top view of a tiled display device 300C in accordance with some embodiments of the present disclosure. The tiled display device 300C may include a plurality of first panels 100E and second panels 100F. The arrangement of the first panel 100E is the same as that of the second panel 100F. The tiled display device 300C shown in FIG. 5 is similar to the tiled display device 300B shown in FIG. 4, and one of the difference is that the first column may be an arrangement of the green pixel unit (vertical screentone) and the red pixel unit (dot screentone) disposed alternatively from top to bottom, the second column may be an arrangement of only the blue pixel units (oblique screentone), and the third column may be an arrangement of the red pixel unit (dot screentone) and the green pixel unit (vertical screentone) alternatively from top to bottom. The pixel units of the first column and the third column in the same row have different colors. The pixel units in the same row are arranged along the X-direction.

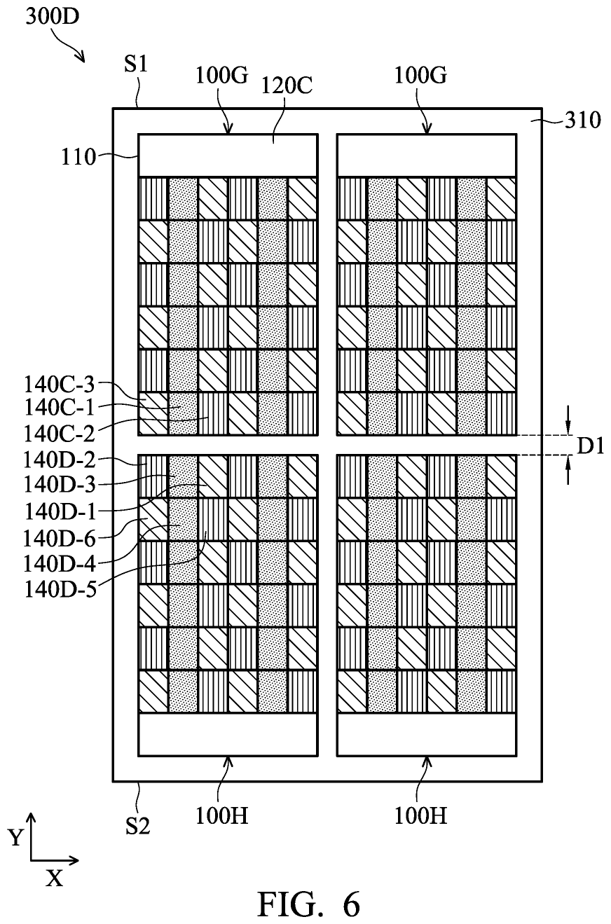

FIG. 6 is a top view of a tiled display device 300D in accordance with some embodiments of the present disclosure. The tiled display device 300D may include a plurality of first panels 100G and second panels 100H. The arrangement of the first panel 100G is the same as that of the second panel 100H. The tiled display device 300D shown in FIG. 6 is similar to the tiled display device 300B shown in FIG. 4, and one of the difference is that the first column may be an arrangement of the green pixel unit (vertical screentone) and the blue pixel units (oblique screentone) disposed alternatively from top to bottom, the second column may be an arrangement of only the red pixel unit (dot screentone), and the third column may be an arrangement of the blue pixel units (oblique screentone) and the green pixel unit (vertical screentone) disposed alternatively from top to bottom. The pixel units of the first column and the third column in the same row have different colors.

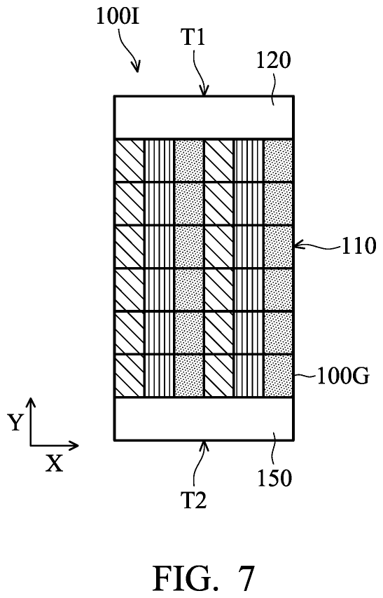

FIG. 7 is a top view of a first panel 100I in accordance with some embodiments of the present disclosure. The first panel 100I is similar to the first panel 100A, and one of the differences is that the first panel 100I further includes a first additional circuit portion 150. In this embodiment, the first additional circuit portion 150 is disposed on the front surface of the first substrate 110 and is able to be bent to the backside of the first substrate 110 depends on the requirements. The first additional circuit portion 150 may be disposed adjacent the second side T2 of the first panel 100I. In some embodiments, the first additional circuit portion 150 may be disposed in the edge area other than the first side T1 and the second side T2. The elements, circuits, and coupling configuration between the first additional circuit portion 150 and the pixel units is similar to those of the first circuit portion 120, and are not repeatedly described herein. In some embodiments, the first additional circuit portion 150 and the first circuit portion 120 may be coupled to different pixel units. However, the scope of the disclosure is not intended to be limiting. In some embodiments, the projective area of the first additional circuit portion 150 in normal direction may be the same as or different from that of the first circuit portion 120.

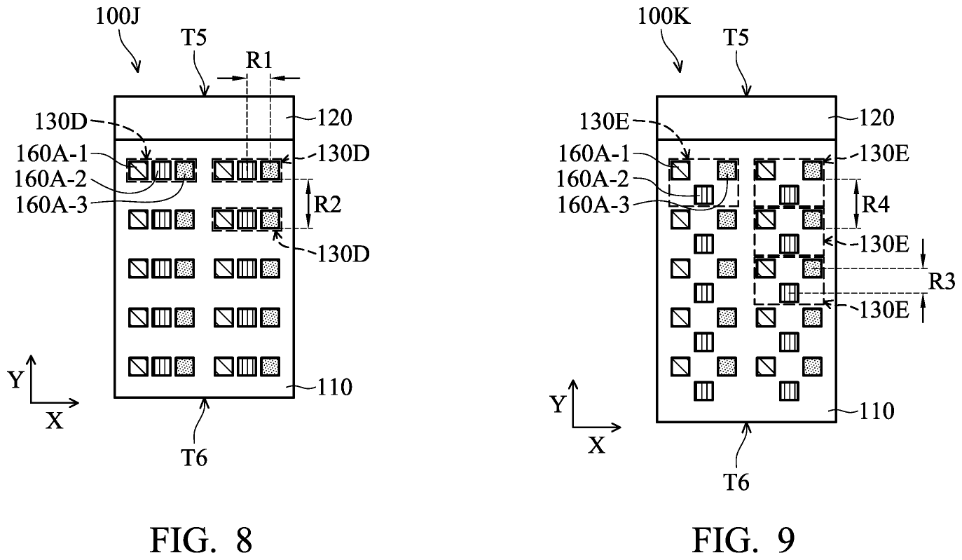

FIG. 8 is a top view of a first panel 100J in accordance with some embodiments of the present disclosure. The first panel 100J may have a plurality of display portions 130D. One display portion 130D may have, but is not limited to, a first pixel unit 160A-1, a second pixel unit 160A-2 and a third pixel unit 160A-3. The first pixel unit 160A-1, the second pixel unit 160A-2 and the third pixel unit 160A-3 are similar to or the same as the first pixel unit 140A-1, the second pixel unit 140A-2 and the third pixel unit 140A-3 in FIG. 1A. In this embodiment, the first pixel unit 160A-1, the second pixel unit 160A-2 and the third pixel unit 160A-3 may be arranged along the X-direction. However, the scope of the disclosure is not intended to be limiting. The first pixel unit 160A-1 may be a blue pixel unit (oblique screentone), the second pixel unit 160A-2 may be a green pixel unit (vertical screentone) and the third pixel unit 160A-3 may be a red pixel unit (dot screentone). However, the scope of the disclosure is not intended to be limiting, and the color of the pixel units may be modified in accordance with the real demands. In this embodiment, the plurality of display portions 130D may be arranged along the X-direction and the Y-direction. However, the scope of the disclosure is not intended to be limiting. The first panel 100J may have a first circuit portion 120 adjacent to the first side T5 of the first panel 100J. In some embodiments, there is a unit pitch R1 between two adjacent pixel units (e.g. the first pixel unit 160A-1 and the second pixel unit 160A-2). The unit pitch R1 may be the distance between the corresponding points (such as centers) of two neighboring pixel units of two pixel units along the X-direction. In addition, when the pixel unit is a micro light-emitting diode or a mini light-emitting diode, the area occupied by the pixel unit may be defined as the area of a package projected to the first panel 100J, wherein the package is a package of at least one micro light-emitting diode or at least one mini light-emitting diode. However, the scope of the disclosure is not intended to be limiting. In some embodiments, the area occupied by the pixel unit may be defined as the area of at least one opening of patterned light shielding elements. The light shielding element may be a black matrix (BM) or light-shielding adhesive gel. However, the scope of the disclosure is not intended to be limiting. When the pixel unit is an organic light-emitting diode, the area occupied by the pixel unit may be defined by the pixel definition layer. However, the scope of the disclosure is not intended to be limiting. When the pixel unit includes liquid crystal material, the area occupied by the pixel unit may be defined by the area of at least one opening in the black matrix (BM) layer. However, the scope of the disclosure is not intended to be limiting.

Furthermore, as shown in FIG. 8, there is a pitch R2 between two adjacent display portions 130D in the Y-direction. The pitch R2 may be defined as the distance between two adjacent display portions 130D in the Y-direction. For example, the pitch R2 may be the distance between the corresponding points (such as centers) of the red unit pixels of two adjacent display portions 130D in the Y-direction. However, the scope of the disclosure is not intended to be limiting. The pitch R2 may be the distance between an arbitrary point of one pixel unit in a display portion 130D and the corresponding point of the corresponding pixel unit in an adjacent display portion 130D disposed in the Y-direction. The pitch R2 may be different from or equivalent to the unit pitch R1.

FIG. 9 is a top view of a first panel 100K in accordance with some embodiments of the present disclosure. The first panel 100K is similar to the first panel 100J shown in FIG. 8, and one of the differences is that the arrangement of the blue unit pixel (oblique screentone), the red unit pixel (dot screentone) and the green unit pixel (vertical screentone) in a display portion 130E of the first panel 100K is different from that of the first panel 100J. In this embodiment, the blue unit pixel, the red unit pixel and the green unit pixel of the display portion 130E are not aligned along the X-direction. The arrangement of the blue unit pixel, the red unit pixel and the green unit pixel of the display portion 130E may be a “A” shape. However, the scope of the disclosure is not intended to be limiting. For example, there is a pitch R3 between two neighboring pixel units in the same display portion 130E (e.g. between the red unit pixel and the green unit pixel or between the blue unit pixel and the green unit pixel). The pitch R3 may be defined as the distance between the centers or the corresponding points of two pixel units along the Y-direction. In some embodiments, a portion of the second pixel unit 160A-2 is located between the first pixel unit 160A-1 and the third pixel unit 160A-3 in the Y-direction. In some embodiments, the second pixel unit 160A-2 is not located between the first pixel unit 160A-1 and the third pixel unit 160A-3 in the Y-direction.

Furthermore, as shown in FIG. 9, there is a pitch R4 between two adjacent display portions 130D in the Y-direction. The pitch R4 may be defined as the distance between two adjacent display portions 130D in the Y-direction. For example, the pitch R4 may be the distance between an arbitrary point of one pixel unit in a display portion 130E and the corresponding point of the corresponding pixel unit in an adjacent display portion 130E disposed in the Y-direction. For example, the pitch R4 may be the distance between the corresponding points (such as centers) of the blue unit pixels (or the green pixel unit) of two adjacent display portions 130D in the Y-direction. However, the scope of the disclosure is not intended to be limiting. In some embodiments, the pitch R4 may be different from or equivalent to the unit pitch R3. Many variations and/or modifications can be made to embodiments of the disclosure. In some embodiments, the locations of the blue unit pixel, the red unit pixel and the green unit pixel of the display portion 130E may be exchanged. However, the scope of the disclosure is not intended to be limiting.

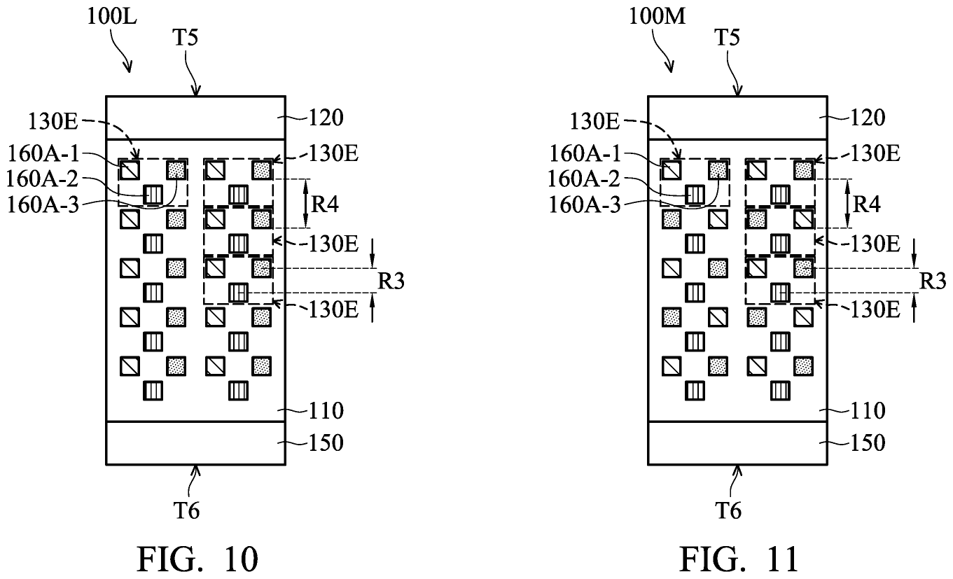

FIG. 10 is a top view of a 100L in accordance with some embodiments of the present disclosure. The 100L is similar to the first panel 100K shown in FIG. 9, and one of the differences is that the 100L further includes the first additional circuit portion 150. The first circuit portion 120 and the first additional circuit portion 150 are adjacent to the first side T5 and the second side T6 that is opposite to the first side T5, respectively.

FIG. 11 is a top view of a first panel 100M in accordance with some embodiments of the present disclosure. The first panel 100M is similar to the 100L shown in FIG. 10, and one of the differences is that the arrangement of the blue unit pixels (oblique screentone), the red unit pixels (dot screentone) and the green unit pixels (vertical screentone) of two adjacent display portions 130E of the first panel 100M is different from that of the 100L. As shown in FIG. 11, the blue pixel unit of the display portion 130E is adjacent to the red pixel unit of adjacent display portion 130E in the Y-direction, the green pixel unit of the display portion 130E is adjacent to the green pixel unit of adjacent display portion 130E in the Y-direction, and the red pixel unit of the display portion 130E is adjacent to the blue pixel unit of another display portion 130E in the Y-direction. However, the scope of the disclosure is not intended to be limiting. The configuration of the first panel 100M in FIG. 11 is similar to the first panels 100C-100H in FIGS. 4-6. The arrangement of the pixel units with different colors may have a rotational symmetry. The aforementioned colors are merely exemplary and not limited, and the scope of the disclosure is not intended to be limiting. The aforementioned colors of the pixel unit may be exchanged if the arrangement is in accordance with the rotational symmetry.

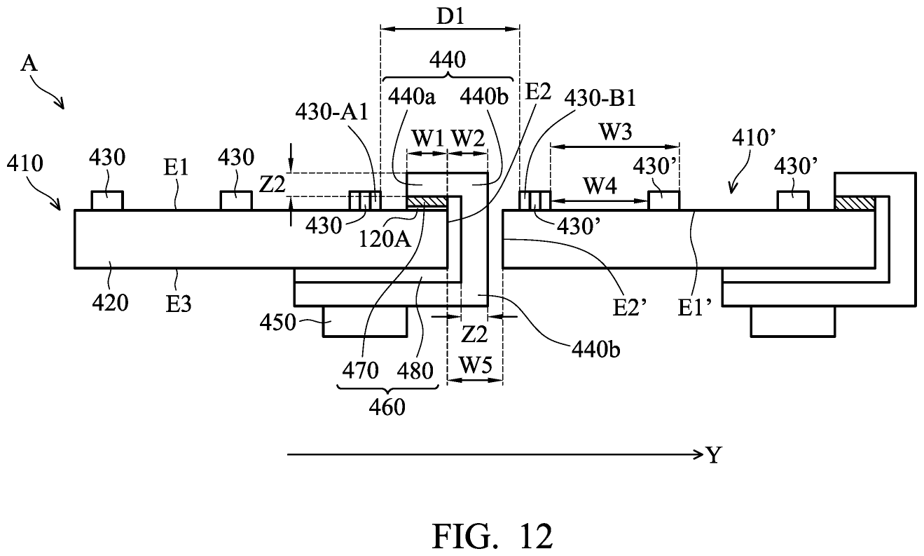

FIG. 12 is a cross-sectional view of an enlarged view A of a tiled display device shown in FIG. 14 in accordance with some embodiments of the present disclosure. In some embodiments, the tiled display device includes a circuit board 440. The circuit board 440 may be disposed on a first top surface E1 and a first side surface E2 that is connected to the first top surface E1 of a first panel 410. In some embodiments, the circuit board 440 may include a first portion 440a and a connected portion 440b. The first portion 440a may be disposed on a portion of the first top surface E1, and the connected portion 440b may be connected to the first portion 440a and disposed on the first side surface E2. In some embodiments, the connected portion 440b is located between the first panel 410 and a second panel 410′. However, the scope of the disclosure is not intended to be limiting. In some embodiments, as shown in FIG. 12, the first pixel unit 430-A1 is the nearest to a display portion 430′ of the second panel 410′, and the sum of the width W1 of the first portion 440a and the width W2 of the connected portion 440b in the Y-direction is less than the first distance D1 between a first pixel unit 430-A1 and a fourth pixel unit 430-B1. As shown in FIG. 12, the fourth pixel unit 430-B1 is corresponding and adjacent to the first pixel unit 430-A1. The first distance D1 may be defined as the shortest distance between the first pixel unit 430-A1 and the fourth pixel unit 430-B1 in the Y-direction. In some embodiments, the circuit board 440 may be electrically connected to the first circuit portion 120A. As shown in FIG. 12, the first pixel unit 430-A1 and the fourth pixel unit 430-B1 may be disposed on the first top surface E1 of the first substrate 410 and first top surface E1′ of the second panel 410′ respectively.

It should be noted that the Y-direction may have different definitions in different situations. For example, when an angle constituted by the first side surface E2 and the first top surface E1 is substantially a right angle (the angle in a range between 85° and 95°), the Y-direction may be defined as the normal direction of the first side surface E2. when an angle constituted by the first side surface E2 and the first top surface E1 is not a right angle (the angle not in a range between 85° and 95°), there may be a corner edge between the first top surface E1 and the first side surface E2. The corner edge has an extension direction, and the direction that is perpendicular to the extension direction and parallel to the first top surface E1 may be defined as the Y-direction. Alternatively, in some embodiments, when an angle constituted by the first side surface E2 and the first top surface E1 is not a right angle (the angle not in a range between 85° and 95°), and there is no apparent corner edge between the first top surface E1 and the first side surface E2, the center of the first top surface E1 of the first panel 410 and the center of the first top surface E1′ of the second panel 410′ may be connected to form a virtual line. The Y-direction may be defined as the extension direction of the virtual line. Furthermore, there may be a gap between the first side surface E2 and a second side surface E2′. The direction that is perpendicular to the extension direction of the gap and parallel to the first top surface E1 may be defined as the Y-direction.

In some embodiments, as shown in FIG. 12, the first panel 410 and the second panel 410′ may be a combination of the first panel 100A and the second panel 100B or a combination of the first panel 100C and the second panel 100D. In some embodiments, the first panel 100A or the second panel 100B may be replaced by one of the first panels 100E-100L. However, the scope of the disclosure is not intended to be limiting. In some embodiments, the circuit board 440 may have a first portion 440a and a connected portion 440b. The first portion 440a may be disposed on the first top surface E1 of the first panel 410, and the connected portion 440b may be disposed on the first side surface E2 and the first bottom surface E3 of the first panel 410. The first bottom surface E3 is opposite to the first top surface E1, and the first side surface E2 may be disposed between the first top surface E1 and the first bottom surface E3 and connected to them. In some embodiments, the connected portion 440b may be located between the first panel 410 and the second panel 410′.

As shown in FIG. 12, the tiled display device further includes a conductive adhesive 470. As shown in FIG. 12, the conductive adhesive 470 may be disposed on the first top surface E1 of the first panel 410. However, the scope of the disclosure is not intended to be limiting. In some embodiments, the conductive adhesive 470 may be disposed on the first side surface E2 of the first panel 410. However, the scope of the disclosure is not intended to be limiting. In some embodiments, the conductive adhesive 470 may be formed between the circuit board 440 and the first top surface E1 on the first panel 410. The configuration of the conductive adhesive 470 may enhance the coupling between conductive pads (not shown) of the circuit board 440 and conductive pads (not shown) of the first top surface E1, or enhance the stability of adhesion between the circuit board 440 and the first top surface E1. In some embodiments, the conductive adhesive 470 may be an anisotropic conductive film (ACF) or an adhesive element including conductive particles. However, the scope of the disclosure is not intended to be limiting. As shown in FIG. 12, the tiled display device may further include an adhesive element 480. The adhesive element 480 may be disposed between the first panel 410 and the circuit board 440. More specially, in some embodiments, the adhesive element 480 may be in direct contact with at least one of the first side surface E2 or the first bottom surface E3 of the first panel 410. The material of the adhesive element 480 may include, but is not limited to, double-sided tape, silicone, light-curing adhesive (such as UV adhesive), epoxy resin adhesive, acrylic adhesive, moisture curing adhesive, optical clear adhesive (OCA), optical transparent resin (OCR). In some embodiments, the adhesive element 480 may have a plurality of non-continuous adhesive portions, these adhesive portions may include the same or different materials. In some embodiments, the space composed by the first bottom surface E3, the first side surface E2 and the circuit board 440 may include air. In some embodiments, when the adhesive element 480 is disposed on the first bottom surface E3 and the circuit board 440, the possibility of breakdown of a chip 450 on the circuit board 440 due to abnormal shaking is decreased. In some embodiments, when the adhesive element 480 is disposed between the first side surface E2 and the circuit board 440, it enhances the adhesion between the circuit board 440 and the first panel 410. As a result, the deformation or the broken of the circuit board 440 (e.g. the connected portion 440b) because of outer force may be decreased. Therefore, the quality of the tiled display device is improved.

In some embodiments, the circuit board 440 has a first thickness Z2. The first thickness Z2 may be defined as the maximum thickness measured in Y-direction of the portion, which is disposed on the first side surface E2, of the circuit board 440. In some embodiments, the connected portion 440b of the circuit board 440 has a different thickness. In some embodiments, the first portion 440a and the connected portion 440b have different thicknesses. In some embodiments, the first portion 440a has a width W1 in the Y-direction. The width W1 may be defined as the maximum width of the first portion 440a in the Y-direction. The first portion 440a may be defined as the portion of the circuit board 440 which is disposed on the first top surface E1, and the connected portion 440b may be defined as the portion of the circuit board 440 which is not disposed on the first top surface E1. In some embodiments, the connected portion 440b has the width W2 in the Y-direction. The width W2 may be defined as the maximum width of the connected portion 440b in the Y-direction. In some embodiments, the sum of the width W1 and the width W2 is less than a unit distance W3 which is a pitch between two adjacent display portions 430′ of the second panel 410′ (or a pitch between two adjacent display portions 430 of the first panel 410) in the Y-direction. For example, the unit distance W3 may be the distance between the seventh pixel unit and the fourth pixel unit shown in FIG. 4. The unit distance W3 may be defined as the distance of the corresponding points (such as the center points) of two adjacent display portions 430′ of the second panel 410′ (or the display portions 430 of the first panel 410) in the Y-direction. Alternatively, the unit distance W3 may be defined as the distance of the corresponding points (such as the center points) of the pixel units with the same color of two adjacent display portions 430′ of the second panel 410′ (or the display portions 430 of the first panel 410) in the Y-direction. In some embodiments, the sum of the width W1 and the width W2 is less than a first unit distance W4. The first unit distance W4 may be defined as the minimal distance between the pixel units of two adjacent display portions 430′ (or the display portions 430 of the first panel 410) in the Y-direction. In this embodiment, there is a second distance W5 between the first side surface E2 of the first panel 410 and the second side surface E2′ of the second panel 410′. The first side surface E2 is adjacent to the second side surface E2′. In addition, the first side surface E2 and the second side surface E2′ face each other. The second distance W5 may be defined as the maximum distance between the first side surface E2 and the second side surface E2′ in the Y-direction. In some embodiments, the second distance W5 may be less than the unit distance W3. In some embodiments, the difference between the first unit distance W4 and the first distance D1 is less than 10% of the first unit distance W4. However, the scope of the disclosure is not intended to be limiting. In some embodiments, the difference between the first unit distance W4 and the first distance D1 is less than 5% of the first unit distance W4. In some embodiments, the difference between the first unit distance W4 and the first distance D1 is less than 3% of the first unit distance W4. In some embodiments, the difference between the first unit distance W4 and the first distance D1 is less than 2% of the first unit distance W4. In some embodiments, the ratio of W4/D1 may be in a range of 0.9 and 1.1 (0.9<W4/D1<1.1). In some embodiments, the ratio of W4/D1 may be in a range of 0.95 and 1.05 (0.95<W4/D1<1.05). In some embodiments, the ratio of W4/D1 may be in a range of 0.97 and 1.03 (0.97<W4/D1<1.03). In some embodiments, the ratio of W4/D1 may be in a range of 0.98 and 1.02 (0.98<W4/D1<1.02). In some embodiments, the difference between the first unit distance W4 and the D1 can be decreased by disposing the connected portion 440b in the gap between the first panel 410 and the second panel 410′. As a result, the quality of the tiled display device is enhanced.

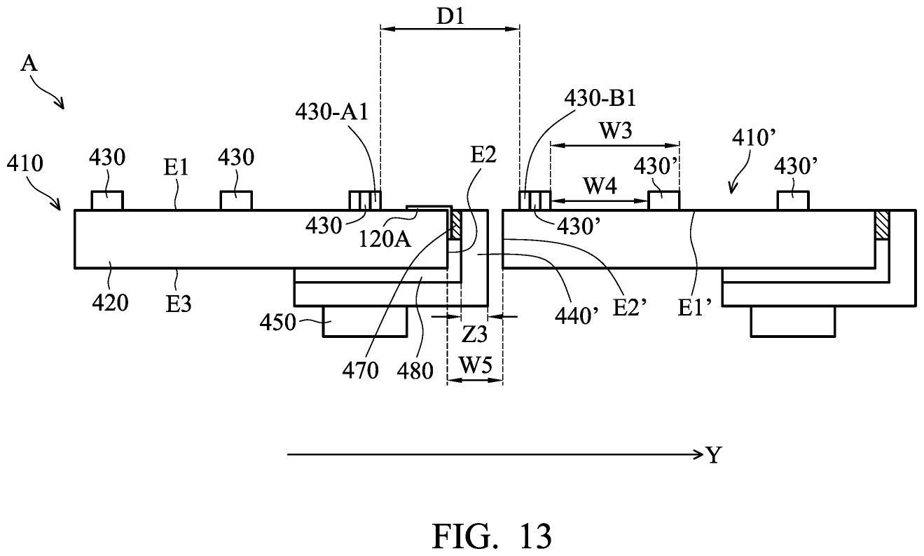

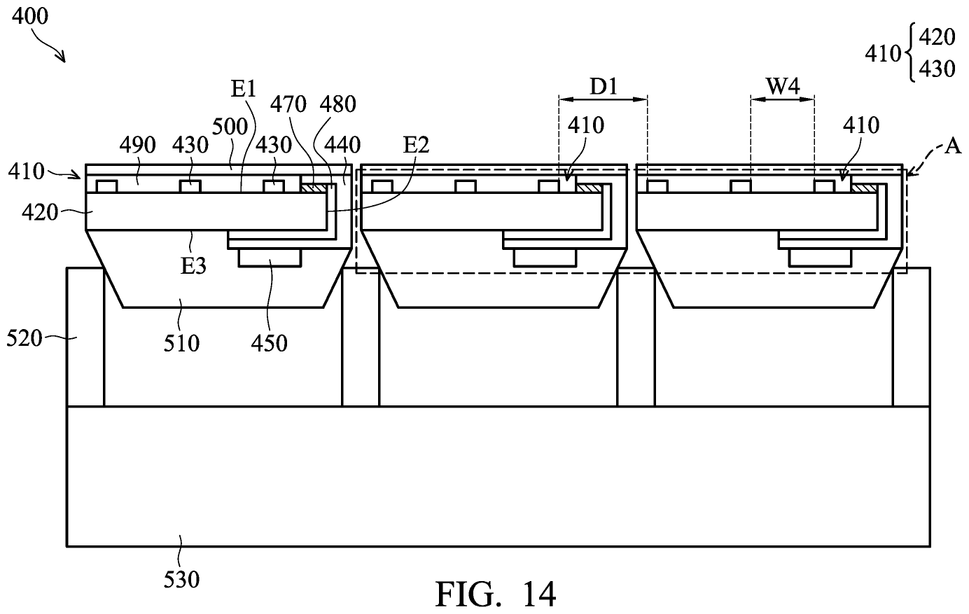

FIG. 13 is a cross-sectional view of an enlarged view A of a tiled display device shown in FIG. 14 in accordance with some embodiments of the present disclosure. The tiled display device shown in FIG. 13 is similar to that shown in FIG. 12, and one of the differences is that the circuit board 440′ may be disposed on the first side surface E2 and the first bottom surface E3. The circuit board 440′ is not disposed on the first top surface E1 of the first panel 410. In this embodiment, the first thickness Z3 of the circuit board 440′ is less than the unit distance W3. In this embodiment, the conductive adhesive 470 may be disposed on the first side surface E2, but the scope of the disclosure is not intended to be limiting. In this embodiment, the first circuit portion 120A may be disposed on the first top surface E1 and the first side surface E2. In some embodiments, the conductive pads of the first circuit portion 120A may be disposed on the first side surface E2, and the conductive pads of the first circuit portion 120A are coupled to the conductive pads of the circuit board 440′ through the conductive adhesive 470. In some embodiments, as shown in FIG. 13, there is a frame region between the first side surface E2 and the display portion 430 that is the nearest to the second panel 410′ in the Y-direction. The width of the frame region in the Y-direction is less than the first unit distance W4. In some embodiments, there is no frame region between the first side surface E2 and the display portion 430 that is the nearest to the second panel 410′ in the Y-direction. The edge of display portion 430, which is the nearest to the second panel 410′, is substantially close to the first side surface E2 in the normal direction of the first top surface E1.

The difference between the first unit distance W4 and the first distance D1 can be decreased by disposing the circuit board 440′ in the gap between the first panel 410 and the second panel 410′. When the difference between the first unit distance W4 and the first distance D1 is less than 10% or even less than 2% of the first unit distance W4, the quality of the tiled display device is enhanced.

FIG. 14 is a cross-sectional view of a tiled display device 400 in accordance with some embodiments of the present disclosure. The tiled display device 400 may include a plurality of first panels 410. FIG. 14 illustrates that the tiled display device 400 includes three first panels 410. However, the number of the first panel 410 is merely an example and not limited, and the scope of the disclosure is not intended to be limiting. The first panel 410 may be aforementioned first panel and/or second panel. In some embodiments, the first panel 410 may include the substrate 420 and a plurality of display portions 430. In some embodiments, the first panel 410 may include one or more circuit portions (such as the first circuit portion 120 or the first additional circuit portion 150). In some embodiments, the display portion 430 may be disposed on the substrate 420 (e.g. the first substrate 110A or the second substrate 110B). The display portion 430 may include a blue unit pixel, a red unit pixel, a green unit pixel or other pixel units with different color. However, the scope of the disclosure is not intended to be limiting. In some embodiments, the tiled display device 400 may include the circuit board 440. In some embodiments, the circuit board 440 may be a flexible printed circuit board (FPCB). However, the scope of the disclosure is not intended to be limiting. In some embodiments, the plurality of conductive pads (not shown) on the circuit board 440 may be coupled to the chip 450. The chip 450 may include a scan driver chip, a scan driver chip or a timing controller driver chip, however, the scope of the disclosure is not intended to be limiting. In some embodiments, the chip 450 may be disposed under the first bottom surface E3. For example, in some embodiments, the chip 450 may be disposed between the first bottom surface E3 and the connected portion 440b.

In some embodiments, as shown in FIG. 14, the tiled display device 400 may include a dielectric layer 490. The dielectric layer 490 may be disposed on the first top surface E1 of the first panel 410 and the display portion 430. In some embodiments, the dielectric layer 490 is configured to compensate the step between the display portion 430 and the circuit board 440 so as to form a planar top surface. As a result, a capping element 500 may be easily disposed on the top surface of the dielectric layer. In some embodiments, the dielectric layer 490 may be a transparent and insulation material. The material of the dielectric layer 490 is selected from the materials which do not have an influence on the quality of light-emitting and do not cause leakage between the display portions 430. The materials of the dielectric layer 490 may include resin or other suitable material. In some embodiments, the material of the capping element 500 may be, but is not limited to, a transparent material such as glass or plastic. The capping element 500 is configured to protect the panel from external impact, moisture, oxygen or other foreign matter.

In some embodiments, as shown in FIG. 14, the tiled display device 400 may include a panel substrate 510. In some embodiments, the first panel 410 may be disposed on the panel substrate 510. In some embodiments, the panel substrate 510 may have a groove structure. As shown in FIG. 14, the panel substrate 510 may have an inverted trapezoid structure. The circuit board 440, the chip 450 may be located between the panel substrate 510 and the first bottom surface E3 of the first panel 410. Namely, the circuit board 440 and the chip 450 may be located in the groove structure of the panel substrate 510. However, the scope of the disclosure is not intended to be limiting. In some embodiments, the groove structure may have, but is not limited to, a rectangle shape, an arc shape or any other suitable shape. In some embodiments, there is a plurality of conductive wires (not shown) in the panel substrate 510, and the conductive wires may be electrically connected to, but is not limited to, the chip 450. In some embodiments, the substrate board 530 may include, but is not limited to, conductive wires, conductive elements, insulative elements therein.

In some embodiments, as shown in FIG. 14, the tiled display device 400 may further include a support element 520 and a substrate board 530. In some embodiments, the support element 520 may be disposed between the substrate board 530 and the panel substrate 510. In some embodiments, the support element 520 is configured to support the panel substrate 510. In some embodiments, the material of the support element 520 may include, but is not limited to, metal conductive material, transparent conductive material or insulation compound. In some embodiments, the support element 520 may have, but is not limited to, a pillar-shaped element or an o-shape element surrounding the panel substrate 510. In some embodiments, the conductive wires of the substrate board 530 may be coupled to the chip 450 through the conductive wires of the panel substrate 510 and the support element 520 so as to drive the pixel units to emit light. In some embodiments, when the material of the support element 520 is electrically insulative, the panel substrate 510 may be designed to have at least one opening (not shown), and the panel substrate 510 may have conductive wires (not shown). The conductive wires may be coupled to the chip 450 and the conductive wires in the substrate board 530.

Although some embodiments of the present disclosure and their advantages have been described in detail, it should be understood that various changes, substitutions and alterations can be made herein without departing from the spirit and scope of the disclosure as defined by the appended claims. For example, it will be readily understood by those skilled in the art that many of the features, functions, processes, and materials described herein may be varied while remaining within the scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A tiled display device, comprising:
a first panel, comprising:
a first pixel unit;
a second pixel unit; and
a third pixel unit, wherein the second pixel unit is between the first pixel unit and the third pixel unit; and
a second panel adjacent to the first panel, comprising:
a fourth pixel unit corresponding and adjacent to the first pixel unit;
a fifth pixel unit corresponding and adjacent to the second pixel unit;
a sixth pixel unit corresponding and adjacent to the third pixel unit, wherein the fifth pixel unit is between the fourth pixel unit and the sixth pixel unit;
a seventh pixel unit adjacent to the fourth pixel unit, wherein the fourth pixel unit is between the first pixel unit and the seventh pixel unit;
an eighth pixel unit adjacent to the fifth pixel unit, wherein the fifth pixel unit is between the second pixel unit and the eighth pixel unit; and
a ninth pixel unit adjacent to the sixth pixel unit, wherein the sixth pixel unit is between the third pixel unit and the ninth pixel unit;
wherein the second pixel unit, the fifth pixel unit and the eighth pixel unit have a first color, the first pixel unit, the sixth pixel unit and the seventh pixel unit have a second color, the third pixel unit, the fourth pixel unit and the ninth pixel unit have a third color, and the first color, the second color and the third color are different colors.

2. The tiled display device as claimed in claim 1, further comprising:
a first circuit board disposed corresponding to a first side surface of the first panel, wherein at least a portion of the first circuit board is located between the first panel and the second panel, and a first thickness of the first circuit board is less than a first distance between the first pixel unit and the fourth pixel unit.

3. The tiled display device as claimed in claim 2, wherein the first thickness is less than a unit distance between the fourth pixel unit and the seventh unit.

4. The tiled display device as claimed in claim 2, further comprising:
a conductive adhesive disposed between the first panel and the first circuit board.

5. The tiled display device as claimed in claim 1, further comprising:
a conductive adhesive is disposed between the first panel and the second panel.

6. The tiled display device as claimed in claim 1, further comprising:
a first circuit board disposed corresponding to a portion of a first top surface of the first panel and a portion of a first side surface of the first panel, the first side surface connected to the first top surface, wherein the first circuit board has a first portion disposed corresponding to the first top surface and a connected portion connected to the first portion, the connected portion is disposed corresponding to the first side surface and located between the first panel and the second panel, and a sum of a width of the first portion and a thickness of the connected portion is less than a first distance between the first pixel unit and the fourth pixel unit.

7. The tiled display device as claimed in claim 1, further comprising:
a first circuit board disposed corresponding to a first side surface of the first panel and a first bottom surface of the first panel, the first bottom surface is opposite to a first top surface of the first panel, and the first pixel unit is disposed on the first top surface.

8. The tiled display device as claimed in claim 7, further comprising:
an adhesive element, wherein the adhesive element directly contacts at least one of the first side surface and the first bottom surface.

9. The tiled display device as claimed in claim 1, wherein a difference between a first distance between the first pixel unit and the fourth pixel unit and a unit distance between the fourth pixel unit and the seventh pixel unit is less than 10% of the unit distance.

10. The tiled display device as claimed in claim 1, wherein the first panel comprises a first circuit portion disposed on a first top surface of the first panel and adjacent to a first side surface of the first panel.
